(19) United States
(12) Patent Application Publication
(10) Pub. No.: US 2011/0068419 A1
(43) Pub. Date: Mar. 24, 2011

(54) MICROMECHANICAL SYSTEM

(76) Inventors: Jochen Reinmuth, Reutlingen (DE); Jens Frey, Filderstadt (DE); Christian Bierhoff, Reutlingen (DE)

(21) Appl. No.: 12/873,912

(22) Filed: Sep. 1, 2010

(30) Foreign Application Priority Data
Sep. 2, 2009 (DE) 102009029114.8

(51) Int. Cl. H01L 29/84; H01L 21/02

(52) U.S. Cl. 257/415; 438/50; 257/E29.324; 257/E21.002

(57) ABSTRACT

A micromechanical system includes a substrate, a first conductive layer situated above the substrate and a second conductive layer situated above the first conductive layer. The first conductive layer and the second conductive layer are conductively interconnected by a connecting element. The connecting element has a conductive edge surrounding a nonconductive region.

### FIELD OF THE INVENTION

The present invention relates to a micromechanical system and a method for manufacturing a micromechanical system.

### BACKGROUND INFORMATION

In manufacturing electromechanical microstructures (MEMS), it is known that conductive layers of polycrystalline silicon may be placed one above the other vertically. The layers may be used as conductor path layers, electrodes or function layers. This is described in German Patent Application No. DE 10 2007 060 878, for example. The conductive layers, which are initially separated by sacrificial layers, may be exposed by etching processes. It is also known that conductive connections may be created between individual conductive layers. To do so, openings are created in the underlying insulation layer before applying a conductive layer situated at a higher level, so that a conductive connection to the deeper conductive layer is formed simultaneously when the conductive layer is applied. This results in an irregular elevation profile (topography) on the surface of the newly applied conductive layer, thus hindering the manufacturing of high-resolution structures. If the connecting elements are designed to be smaller, this reduces the interfering influences of the topography. However, there is a marked decline in the mechanical stability of the connecting elements at the same time.

### SUMMARY OF THE INVENTION

An object of the present invention is to provide a micromechanical system having an improved connection between two conductive layers. This object is achieved by a micromechanical system according to the present invention. In addition, an object of the present invention is to provide a method for manufacturing a micromechanical system having an improved connection between two conductive layers. This object is achieved by a method according to the present invention.

A micromechanical system according to the present invention includes a substrate, a first conductive layer situated above the substrate and a second conductive layer situated above the first conductive layer. The first conductive layer and the second conductive layer are conductively interconnected by a first connecting element. The first connecting element has a first conductive edge which surrounds a first nonconductive region. The second conductive layer advantageously has only a low topography over the connecting element. The connecting element nevertheless has a very high mechanical stability. One particular advantage is that mechanical elastic and torsion properties of the connecting element are adjustable by varying the volume and the material composition of the nonconductive region.

In a specific embodiment of the micromechanical system, the first nonconductive region has an oxide. This advantageously produces a particularly stable connection between the first and second conductive layers.

The first conductive edge expediently has a ring shape.

In one refinement, the first conductive edge surrounds another conductive region extending from the first conductive layer to the second conductive layer. This advantageously makes it possible to increase the conductivity of the connecting element. Furthermore, the further conductive region may also border a nonconductive region. Such a chamber structure makes it possible to design the mechanical properties of the connecting element as desired.

A wall thickness of the first conductive edge parallel to the substrate surface is preferably smaller than twice the thickness of the second conductive layer in the direction perpendicular to the substrate surface. The surface of the second conductive layer then advantageously has only a slight variation in height (topography).

In one refinement, the micromechanical system has a third conductive layer situated above the second conductive layer in such a way that the second conductive layer and the third conductive layer are conductively interconnected by a second connecting element. The second connecting element has a second conductive edge surrounding a second nonconductive region. The additional conductive layer of this micromechanical system may advantageously be used for manufacturing conductor path intersections, for example. The surface of the third conductive layer advantageously has only a low topography.

The second conductive edge is in particular preferably situated with an offset relative to the first conductive edge in a direction parallel to the substrate surface. The creation of an excessively strong topography in the surfaces of the conductive layers is advantageously prevented by such an offset placement, for example, a cascading placement of the connecting elements.

A method according to the present invention for manufacturing a micromechanical system has method steps for providing a substrate with a first conductive layer, for depositing and structuring a second insulating layer, creating, in the second insulating layer, a trench extending from the surface of the second insulating layer to the first conductive layer and bordering a section of the second insulating layer, for depositing a second conductive layer and for removing a portion of the second insulating layer. This method advantageously allows the manufacture of a mechanically stable connection between the first and second conductive layers and therefore creates only minor differences in height in the surface of the second conductive layer. Another advantage is that the mechanical properties of the conductive connection between the conductive layers are adaptable to the particular requirements.

For providing the substrate with the first conductive layer, method steps are expediently performed for providing a substrate, for depositing and structuring a first insulating layer, and for depositing and structuring the first conductive layer.

It is also expedient if at least one through opening is created in the second conductive layer and if the second part of the second insulating layer is removed by an etching process. The region of the second insulating layer bordered by the resulting conductive edge between the first and second conductive layers may advantageously be either removed or retained. This allows the mechanical properties of the connecting element to be varied.

### BRIEF DESCRIPTION OF THE DRAWINGS

FIG. 1 shows a schematic diagram of a micromechanical system according to a first specific embodiment.

FIG. 2 shows a micromechanical system according to a second specific embodiment.

FIG. 3 shows a section through a connecting element of the micromechanical system.

FIG. 4 shows a micromechanical system according to a third specific embodiment.

FIG. 5 shows a section through a connecting element of the micromechanical system.

FIG. 6 shows a micromechanical system according to a fourth specific embodiment.

FIG. 7 shows a micromechanical system according to a fifth specific embodiment.

### DETAILED DESCRIPTION

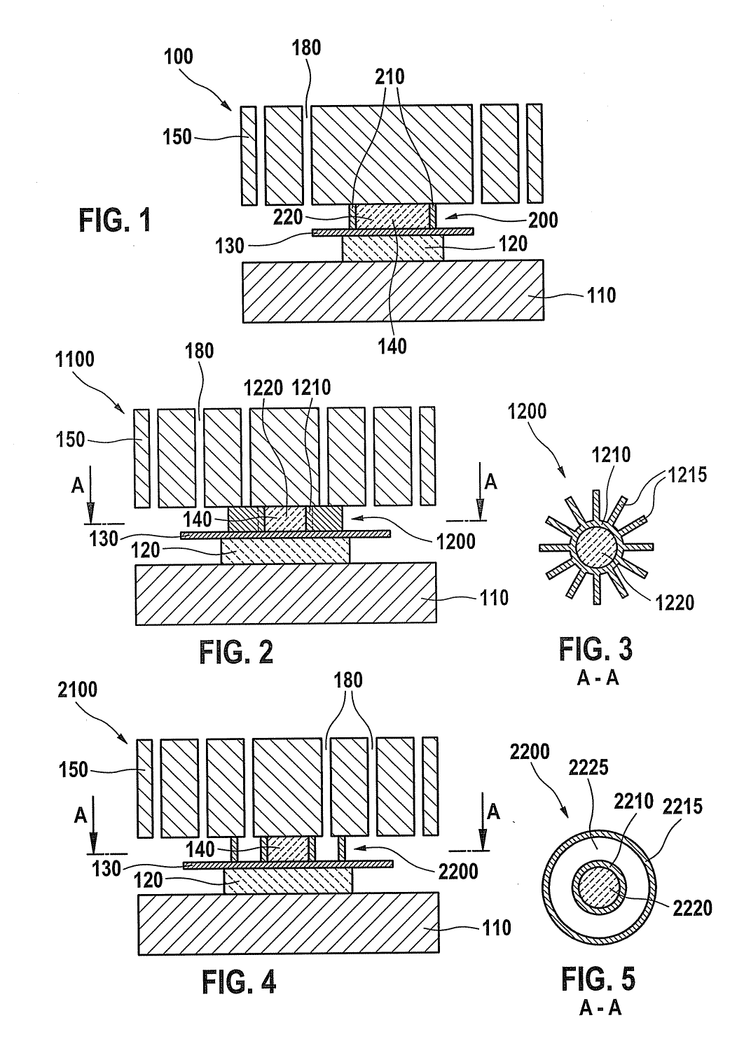

FIG. 1 shows a section through a layer structure of a micromechanical system 100 in a highly schematic diagram. Micromechanical system 100 may be part of a micromechanical sensor structure such as an acceleration sensor or a yaw sensor, for example. Micromechanical system 100 includes a substrate 110, which functions as the carrier. Substrate 110 may be a silicon substrate, for example. A first insulating layer 120 is provided on the surface of substrate 110. First insulating layer 120 is preferably embodied as a sacrificial layer and is made of a silicon oxide, for example. A first conductive layer 130 is situated on first insulating layer 120. First conductive layer 130 may be a buried polysilicon layer, for example. For example, conductor paths may be defined in first conductive layer 130. First conductive layer 130 may also function as an electrode. A second insulating layer 140 is situated above first conductive layer 130. Second insulating layer 140 is preferably also designed as a sacrificial layer and may also be made of a silicon oxide, for example. A second conductive layer 150 is provided above second insulating layer 140. Second conductive layer 150 may be a polysilicon function layer, for example. Second conductive layer 150 may have a greater thickness than first conductive layer 130. For example, movable elements of a sensor structure of micromechanical system 100 may be manufactured from second conductive layer 150. Second conductive layer 150 has one or more trench openings 180, which run perpendicularly to the substrate surface through second conductive layer 150.

First conductive layer 130 and second conductive layer 150 are interconnected by a conductive connecting element 200. Conductive connecting element 200 has a sleeve-shaped edge 210 made of a conductive material extending from first conductive layer 130 to second conductive layer 150. Conductive edge 210, first conductive layer 130 and second conductive layer 150 surround a nonconductive region 220 of connecting element 200. In the example shown in FIG. 1, nonconductive region 220 is formed by a part of second insulating layer 140. Parallel to the surface of substrate 110, connecting element 200 may have a circular cross section, for example. However, other cross sections are also possible, for example, rectangular or polygonal cross sections. Connecting element 200 establishes a mechanically stable connection between first conductive layer 130 and second conductive layer 150. The wall thickness of edge 210 of connecting element 200 in a direction parallel to the surface of substrate 110 is less than twice the thickness of second conductive layer 150 in the direction perpendicular to the surface of substrate 110. In other words, second conductive layer 150 is more than half as thick as the wall thickness of edge 210. The surface of second conductive layer 150 facing away from substrate 110 has only minor differences in height, i.e., only a low topography. The surface of second conductive layer 150 in particular has only a slight recess in the region above edge 210 of connecting element 200. The recess in the surface of second conductive layer 150 perpendicularly above edge 210 is smaller than the thickness of second insulating layer 140.

To manufacture micromechanical system 100 of FIG. 1, first insulating layer 120 is first deposited on the surface of substrate 110 and is suitably structured. First conductive layer 130 is deposited and structured next. Second insulating layer 140 is deposited in the next step. A trench is then created in second insulating layer 140, bordering a section of second insulating layer 140. The trench extends perpendicularly to the surface of substrate 110 throughout the entire second insulating layer 140. The depth of the trench thus corresponds to the thickness of second insulating layer 140. The section of second insulating layer 140 bordered by the trench later forms nonconductive region 220 of connecting element 200. The shape of edge 210 of connecting element 200 is defined by the shape of the trench. Second conductive layer 150 is deposited in the subsequent method step. At the same time, the trench created in second insulating layer 140 is filled, thus forming edge 210 of connecting element 200. Edge 210 and second conductive layer 150 are therefore deposited simultaneously. Only a low topography is formed in the surface of second conductive layer 150 above edge 210 of connecting element 200 because the thickness of second conductive layer 150 is more than half as great as the wall thickness of edge 210, i.e., the width of the trench created in second insulating layer 140. In particular, the surface of second conductive layer 150 is recessed perpendicularly above edge 210 by less than the thickness of second insulating layer 140. Second conductive layer 150 is structured subsequently. One or more trench openings 180 in particular are created, extending through second conductive layer 150 perpendicularly to the surface of substrate 110. Next, in a sacrificial layer process, parts of first insulating layer 120 and of second insulating layer 140 may be removed selectively. The etching medium penetrates through trench openings 180 to insulating layers 120, 140. Nonconductive region 220 of second insulating layer 140 surrounded by edge 210 is protected from the etching medium by edge 210 and is therefore not removed.

FIG. 2 shows a schematic view of a micromechanical system 1100 according to a second specific embodiment, in which connecting element 200 is replaced by a connecting element 1200. Connecting element 1200 has a conductive edge 1210 surrounding a nonconductive region 1220. FIG. 3 shows a section through connecting element 1200 and parallel to the surface of substrate 110. It is discernible here that edge 1210 of connecting element 1200 has a plurality of struts 1215 pointing outward like rays, made, like edge 1210, of the conductive material of second conductive layer 150. Struts 1215 increase the conductivity and mechanical stability of connecting element 1200. The thickness of each strut 1215 corresponds approximately to the wall thickness of edge 1210 and is thus less than twice the thickness of second conductive layer 150. Struts 1215 therefore also produce only a low topography of second conductive layer 150.

FIG. 4 shows a micromechanical system 2100 according to a third specific embodiment. Connecting element 200 of the first specific embodiment has been replaced here by a conductive connecting element 2200 between first conductive layer 130 and second conductive layer 150. FIG. 5 shows a section through connecting element 2200 parallel to the surface of substrate 110. Connecting element 2200 has a hollow cylindrical inner edge 2210 and a hollow cylindrical outer edge 2215, each being made of the conductive material of second conductive layer 150 and extending between first conductive layer 130 and second conductive layer 150. Outer edge 2215 is concentric around inner edge 2210. Inner edge 2210 surrounds an inner nonconductive region 2220, which is filled with the insulating material of second insulating layer 140. An outer nonconductive region 2225 in which the insulating material of second insulating layer 140 has been removed is situated between inner edge 2210 and outer edge 2215. There is thus a vacuum or a gas such as air in outer nonconductive region 2225.

Manufacturing of micromechanical system 2100 differs from the method explained with reference to FIG. 1 in that two concentric trenches are created after applying second insulating layer 140, inner edge 2210 and outer edge 2215 of connecting element 2200 being formed subsequently in these trenches. Furthermore, in structuring of second conductive layer 150, one or more trench openings 180 are also created perpendicularly above outer nonconductive region 2225. These trench openings 180 thus extend from the surface of second conductive layer 150 facing away from substrate 110 through second conductive layer 150 into the region of second insulating layer 140 bordered by outer edge 2215. During the sacrificial layer process for dissolving out portions of first insulating layer 120 and second insulating layer 140, the etching medium may therefore also penetrate into outer nonconductive region 2225 and remove second insulating layer 140 there. It is of course possible to also remove the material of second insulating layer 140 in inner nonconductive region 2220 or to also retain the material of second insulating layer 140 in outer nonconductive region 2225. This results in different mechanical properties of connecting element 2200. The material of second insulating layer 140 may also be removed by creating suitable trench openings 180 from nonconductive region 220 of connecting element 200 of FIG. 1 and nonconductive region 1220 of connecting element 1200 of FIG. 3.

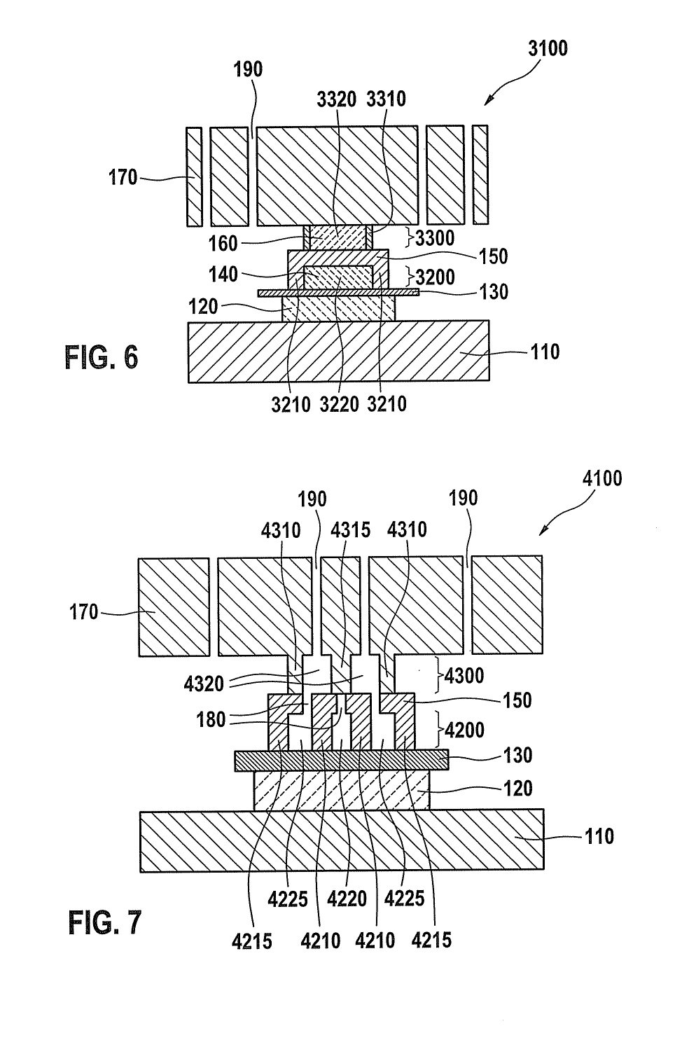

FIG. 6 shows a micromechanical system 3100 according to a fourth specific embodiment, in which, in contrast with micromechanical system 100 of FIG. 1, a third insulating layer 160 and a third conductive layer 170 are situated above second conductive layer 150. These three conductive layers 130, 150, 170 of micromechanical system 3100 allow more complex sensor systems to be manufactured, in which conductor path intersections, for example, are possible. A first conductive connecting element 3200 is situated between first conductive layer 130 and second conductive layer 150. Second conductive layer 150 and third conductive layer 170 are conductively interconnected by a second connecting element 3300. First connecting element 3200 includes a first edge 3210, which is made of the conductive material of second conductive layer 150 and surrounds a first nonconductive region 3220, in which some material of second insulating layer 140 remains. Second connecting element 3300 has a second edge 3310, which is made of the conductive material of third conductive layer 170 and surrounds a second conductive region 3320, in which insulating material of third insulating layer 160 remains. First edge 3210 and second edge 3310 may each have a hollow cylindrical sleeve shape, for example. The wall thickness of first edge 3210 is less than twice the thickness of second conductive layer 150. The wall thickness of second edge 3210 is less than twice the thickness of third conductive layer 170. Second edge 3310 is not situated directly above first edge 3210 in the direction perpendicular to the surface of substrate 110. In the example shown here, second connecting element 3300 has a smaller diameter than first connecting element 3200, so that second edge 3310 is situated perpendicularly above first nonconductive region 3220. The placement of edges 3210, 3310 so they are not directly one above the other has the advantage that topographic recesses in second conductive layer 150 and third conductive layer 170, which are formed in manufacturing connecting elements 3200, 3300, are not additive. Therefore, third conductive layer 170 also has only minor topographical recesses. Third conductive layer 170 also has one or more trench openings 190 through which an etching medium is able to penetrate during a first sacrificial layer process to first, second and third insulating layers 120, 140, 160.

FIG. 7 shows a micromechanical system 4100 according to a fifth specific embodiment. The layer sequence of micromechanical system 4100 corresponds to that of micromechanical system 3100 in FIG. 6. However, first conductive layer 130 and second conductive layer 150 of micromechanical system 4100 are conductively interconnected by a first connecting element 4200. Second conductive layer 150 and third conductive layer 170 are conductively interconnected by a second connecting element 4300. First connecting element 4200 has an inner edge 4210, which is made of the conductive material of second conductive layer 150 and borders an inner nonconductive region 4220. Furthermore, first connecting element 4200 has an outer edge 4215, which concentrically surrounds inner edge 4210, and is made of the material of second conductive layer 150 and borders an outer nonconductive region 4225 situated between inner edge 4210 and outer edge 4215. Second connecting element 4300 has a hollow cylindrical edge 4310, which is made of a material of third conductive layer 170 and connects it conductively to second conductive layer 150. Edge 4310 surrounds a nonconductive region 4320. Furthermore, a cylindrical pin or ram 4315 situated in nonconductive region 4320 is also made of the material of third conductive layer 170 and runs from second conductive layer 150 to third conductive layer 170.

The insulating material of third insulating layer 160 has been removed in nonconductive region 4320. Third conductive layer 170 therefore has one or more trench openings 190 extending from the surface of third conductive layer 170 facing substrate 110 through third conductive layer 170 into nonconductive region 4320. During the sacrificial layer process, the etching medium has been able to penetrate through trench openings 190 into nonconductive region 4320 and remove third insulating layer 160 there. Inner nonconductive region 4220 and outer nonconductive region 4225 of first conducting element 4200 are also not filled with the material of second insulating layer 140. Second insulating layer 150 therefore has one or more trench openings 180, extending from nonconductive region 4320 of second connecting element 4300 through second conducting layer 150 into inner nonconductive region 4220 and outer nonconductive region 4225. The etching medium was also able to penetrate through trench openings 180 into nonconductive regions 4220, 4225 of first connecting element 4200 during the sacrificial layer process and remove the material of second insulating layer 140 there. In alternative specific embodiments, nonconductive regions 4220, 4225, 4320 may of course also remain filled with the insulating material of insulating layers 140, 160.

According to the present invention, the exact shape of the connecting element and their conductive edges may be selected differently. In particular, rectangular or other cross sections are also possible in addition to the circular cross sections shown here. The decisive factor is only that the conductive edge of the particular connecting element surrounds a nonconductive region. The nonconductive region may remain filled with insulating material of a sacrificial layer, resulting in a particularly high mechanical stability of the connecting element. Alternatively, the sacrificial layer material may be removed from the nonconductive region. The edge of the connecting element may advantageously be selected to be so thin that only a low height topography is established in the layer situated above the connecting elements.

What is claimed is:

1. A micromechanical system comprising:
a substrate;
a first conductive layer situated above the substrate;
a second conductive layer situated above the first conductive layer; and
a first connecting element conductively interconnecting the first conductive layer and the second conductive layer, the first connecting element having a first conductive edge surrounding a first nonconductive region.

2. The micromechanical system according to claim 1, wherein the first nonconductive region has an oxide.

3. The micromechanical system according to claim 1, wherein the first conductive edge has a ring shape.

4. The micromechanical system according to claim 1, wherein the first conductive edge surrounds another conductive region extending from the first conductive layer to the second conductive layer.

5. The micromechanical system according to claim 1, wherein a wall thickness of the first conductive edge parallel to a substrate surface is less than twice a thickness of the second conductive layer in a direction perpendicular to the substrate surface.

6. The micromechanical system according to claim 1, further comprising:
a third conductive layer situated above the second conductive layer; and
a second connecting element conductively interconnecting the second conductive layer and the third conductive layer, the second connecting element having a second conductive edge surrounding a second nonconductive region.

7. The micromechanical system according to claim 6, wherein the second conductive edge is situated at an offset with respect to the first conductive edge in a direction parallel to a substrate surface.

8. A method for manufacturing a micromechanical system, comprising:
providing a substrate having a first conductive layer;
depositing and structuring a second insulating layer, a trench extending from a surface of the second insulating layer to the first conductive layer being created in the second insulating layer, the trench bordering a section of the second insulating layer;
depositing a second conductive layer; and
removing a portion of the second insulating layer.

9. The method according to claim 8, wherein the step of providing the substrate with the first conductive layer includes:
providing the substrate;
depositing and structuring a first insulating layer; and
depositing and structuring the first conductive layer.

10. The method according to claim 8, further comprising:
creating at least one through opening in the second conductive layer; and
removing a part of the second insulating layer by an etching process.
